(19) United States
(12) Patent Application Publication
(10) Pub. No.: US 2026/0182098 A1
(43) Pub. Date: Jun. 25, 2026

(54) LED WITH OPTICAL ELEMENT

(71) Applicant: LUMILEDS LLC, San Jose, CA (US)

(72) Inventors: Jeff DiMaria, Scotts Valley, CA (US); Yu-Chen Shen, Sunnyvale, CA (US); Grigoriy Basin, San Francisco, CA (US)

(73) Assignee: LUMILEDS LLC, San Jose, CA (US)

(21) Appl. No.: 19/000,325

(22) Filed: Dec. 23, 2024

(51) Int. Cl. H10H 20/84; H10H 20/01; H10H 20/851

(52) U.S. Cl. CPC H10H 20/84; H10H 20/034; H10H 20/8514

(57) ABSTRACT

A light emitting structure includes one or more optical barriers which may have some gaps or discontinuity in order to decrease the amount of light absorbed by the optical barrier. The optical barrier may have a gap in the vertical direction between it and the substrate, or between it and the top of a side coat, or both. The optical barrier may have a gap or discontinuity in the horizontally direction, so that it does not fully surround the LED or phosphor horizontally. This may increase the light extraction efficiency of the light emitting structure.

### FIELD OF THE INVENTION

The invention relates generally to barriers, particularly optical barriers with spacing for LED light sources.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. LEDs may be combined with one or more wavelength converting materials (generally referred to herein as “phosphors”) that absorb light emitted by the LED and in response emit light of a longer wavelength.

Inorganic LEDs and phosphor converted LEDs may be used to create different types of displays including, for example, augmented-reality (AR) displays, virtual-reality (VR) displays, and mixed-reality (MR) displays.

LEDs may serve as pixels in adaptive automotive forward lighting modules. These modules have requirements on pixel-to-pixel crosstalk, luminance cutoff, and optical efficiency. Pixel-to-pixel crosstalk is undesirable and is typically reduced by increasing spacing between light emitting surfaces (LES). However, increasing spacing results in a wide dark gap between pixels that can be seen on the roadway. In order to reduce this dark gap while maintaining low pixel-to-pixel crosstalk, optically absorbing material between emitters have been proposed. Existing concepts for optical barriers material in automotive forward lighting applications that require high contrast and low crosstalk between pixels cover barrier materials that absorb light uniformly across the visible spectrum which have a black appearance. In order to reduce this dark gap while maintaining low pixel-to-pixel crosstalk, introducing an optically absorbing material between emitters has been proposed. The disadvantage that this introduces is an optical efficiency penalty incurred by the absorbing optical barrier between emitters.

### SUMMARY

Embodiments of an invention include a light emitting device with shaped optical barriers. The optical barriers may be shaped to have one or more of a gap with the substrate, gap with the top of a side coating, and a gap or absence horizontally around the LED and/or phosphor. One or more of these gaps may enhance the light extraction efficiency of the light emitting device as lossy absorption of light may be decreased by the gaps. In other words, the start and end points of the absorber in the vertical dimensions are varied from either the bottom up or top down, or both directions, and/or the start and end points of the absorber in the horizontal dimensions are varied to provide gaps or absences around the LED or phosphor.

Embodiments of the invention may be used in any application that benefits from high contrast (low crosstalk) between pixels, sharp optical cutoff (single or multi emitter), and high optical efficiency. These include, but are not limited to automotive forward lighting, direct-view displays/signage, and camera flash.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 schematically illustrates a cross-sectional view of a light source with an LED and a phosphor, where there is a gap between the optical barrier and the substrate.

FIG. 2 schematically illustrates a cross-sectional view of a light source with an LED and a phosphor, where there is a gap between the optical barrier and the top of the side coating.

FIG. 3 schematically illustrates a cross-sectional view of a light source with an LED and a phosphor, where there is a gap between the optical barrier and the substrate as well as the top of the side coating.

FIG. 4 schematically illustrates a plan view of an array of light emitting devices with optical barriers that do not fully horizontally surround the LED and/or phosphor.

FIG. 5 schematically illustrates a plan view of an array of light emitting devices with optical barriers that do not fully horizontally surround the LED and/or phosphor.

FIG. 6 schematically illustrates a plan view of an array of light emitting devices with optical barriers that do not fully horizontally surround the LED and/or phosphor.

FIG. 7 schematically illustrates a plan view of an array of light emitting devices with optical barriers that do not fully horizontally surround the LED and/or phosphor.

FIG. 8 schematically illustrates a plan view of an array of light emitting devices with optical barriers that do not fully horizontally surround the LED and/or phosphor.

FIG. 9 schematically illustrates a plan view of an array of light emitting devices with a single optical barrier that does not fully horizontally surround the LED and/or phosphor.

FIG. 10 schematically illustrates a plan view of an array of light emitting devices with optical barriers that do not fully horizontally surround the LED and/or phosphor.

FIG. 11 schematically illustrates a plan view of a light emitting device with optical barriers that do not fully horizontally surround the LED and/or phosphor.

FIG. 12 schematically illustrates a plan view of a light emitting device with optical barriers that do not fully horizontally surround the LED and/or phosphor.

FIG. 13 schematically illustrates a plan view of a light emitting device with optical barriers that do not fully horizontally surround the LED and/or phosphor.

FIG. 14 schematically illustrates a cross-sectional view of a LED and phosphor disposed on a tape in a flipped configuration.

FIG. 15 schematically illustrates a cross-sectional view of a LED and phosphor disposed on a tape in a flipped configuration with a side coating trenched partially through.

FIG. 16 schematically illustrates a cross-sectional view of a LED and phosphor disposed on a tape in a flipped configuration with an optical barrier extending partially through the side coating.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

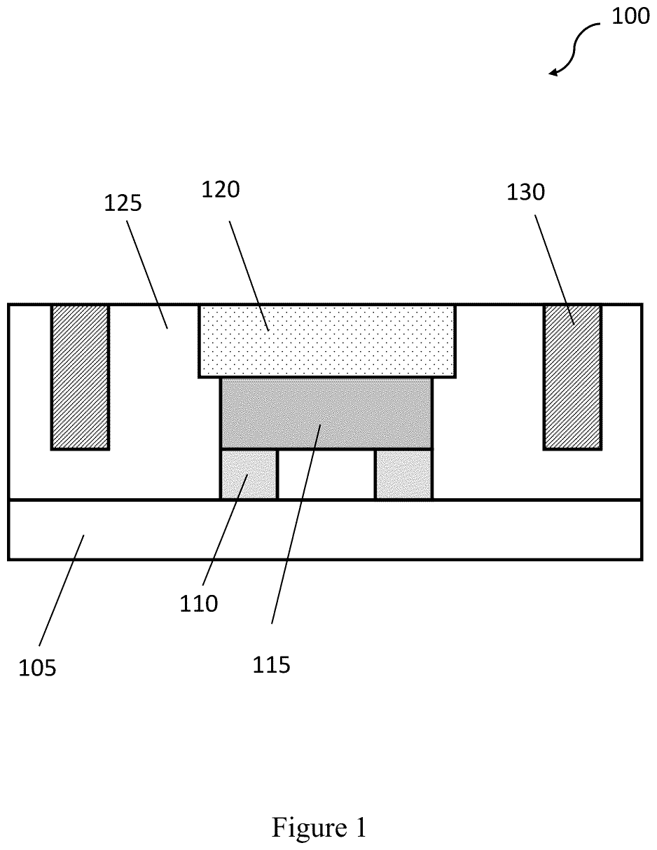

FIG. 1 illustrates a light emitting device with an LED 115, a wavelength converting layer 120 disposed on the LED 115, and an optical barrier 130. The LED 115 is disposed on a substrate 105 via contacts 110. The LED 115 and wavelength converting layer 120 may be disposed in a side coating 125 disposed on a side of the LED 115 and/or the wavelength converting layer 120. The side coating 125 may not include any luminescent material, although this is not a requirement. The side coating 125 may be entirely or partially surrounded by the optical barrier 130, and may include a material such as transparent silicone and particles in the silicone such as TiOₓ (e.g., TiO₂) which improve scattering. The LED 115 emits a light of a first wavelength (e.g., maximum wavelength or wavelength range). The LED 115 emits a light of a first wavelength (e.g., maximum wavelength or wavelength range). The wavelength converting layer 120 may include a luminescent material such as a phosphor, which absorbs light of the first wavelength and emits light of a second wavelength that may be different from the first wavelength. The wavelength converting layer 120 may be ceramic phosphor. In an example, LED 115 may emit blue light while the wavelength converting layer 120 may absorb the blue light and emit yellow light in response. Of course, the emitted and/or absorbed colors of respectively the LED 115 and wavelength converting layer 120 may be any visible color, such as red, blue, green, yellow, or it may be infrared or ultraviolet. The wavelength converting layer 120 may be in direct contact with or spaced apart from the LED 115. In either case, the wavelength converting layer 120 may be in an optical path of the LED 115 such that it absorbs a majority of the light of the first wavelength, although this is not necessary and it may absorb a portion less than a majority of the light of the first wavelength. The optical barrier 130 may be spaced apart from one or both of the wavelength converting layer 120 and/or the LED 115, or may be disposed in direct contact to a side wall of one or both. The optical barrier 130 may be black and/or comprise silicone.

FIGS. 1-3 show a cross section of the light emitting device 100 when viewed looking down a horizontal direction parallel to the plane of substrate 105. When viewed in this direction, the optical barrier 130 may not extend fully through the side coating 125 in a vertical direction perpendicular to the horizontal direction and perpendicular to a plane of the substrate 105 upon which the LED 115 is disposed.

The optical barrier 130 may have a gap between the bottom of the optical barrier 130 (the side facing the substrate 105) and the substrate 105. The optical barrier 130 may have its top surface flush with the top of the side coating 125 and/or may not be in direct contact with the substrate 105. This gap may have a size between greater than 0 micron to 250 microns, such as from 1-200 microns, such as from 5-100 microns. The gap may have a height equal to or greater than the total thickness of the contact 110 and LED 115. The gap may even extend from the substrate 105 to or past the lowest vertical height of the wavelength converting layer 120. Advantageously, the gap may decrease the amount of light absorbed by the optical barrier 130 such that more light is emitted from the light emitting device 100.

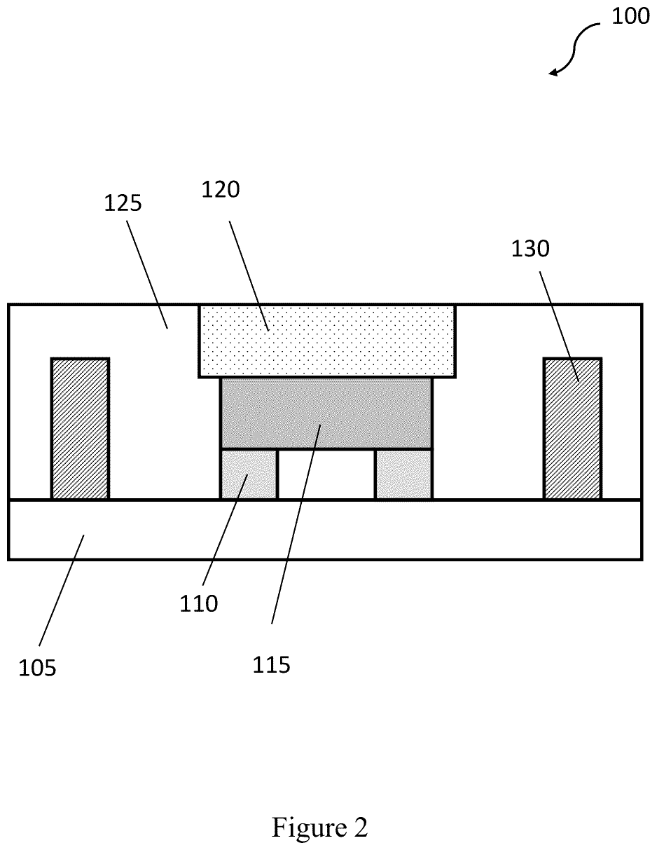

In embodiments of the invention, the optical barrier 130 may have a gap between the top of the optical barrier 130 (the side opposite and/or farthest away from the substrate 105) and the top of the side coating 125. This is shown in FIG. 2. The optical barrier 130 may be in direct contact with the substrate 105 without being flush with the top of the side coating 125 This gap may have a size between greater than 0 micron to 250 microns, such as from 1-200 microns, such as from 5-100 microns. The gap may have a height equal to or greater than the total thickness of the phosphor 120 and LED 115. The gap may even extend from the top of the side coating 125 to or past the lowest vertical height of the LED 115.

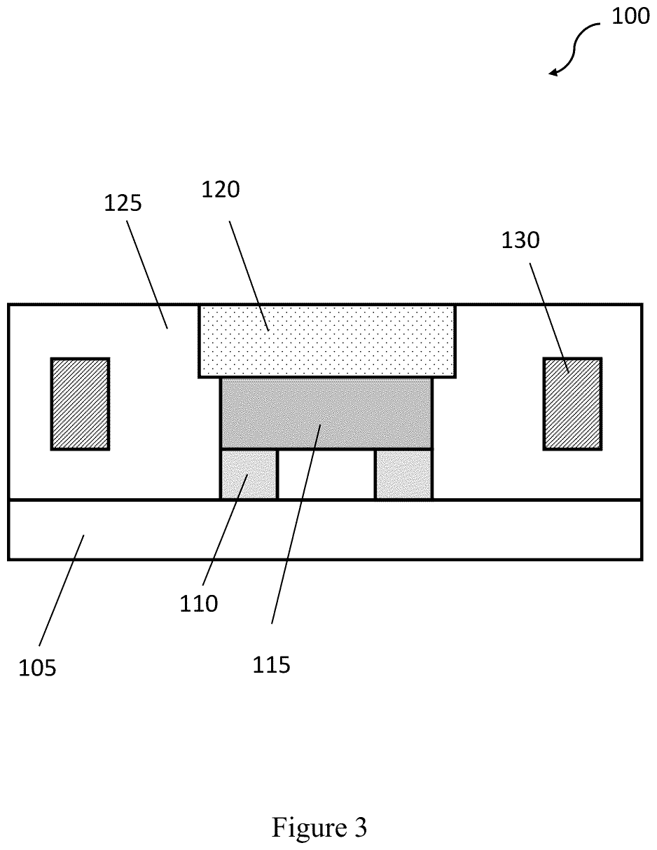

In embodiments of the invention, the optical barrier 130 may have a gap between both the top of the optical barrier 130 and the top of the side coating 125, and between the bottom of the optical barrier 130 and the substrate 105. This is shown in FIG. 3. The optical barrier 130 may be completely surrounded by side coating 125 without being in direct contact with the substrate 105 and without being flush with the top of the side coating 125. The gaps may each have a size between greater than 0 micron to 250 microns, such as from 1-200 microns, such as from 5-100 microns, and may each be placed according to the above description of gaps in FIG. 1 or 2. Even though there is a gap at the top and bottom of the optical barrier 130, the optical barrier 130 may fully horizontally surround the LED 115 while partially or without horizontally surrounding the wavelength converting layer 120, although this is not a requirement. The optical barrier 130 may only partially horizontally surround the wavelength converting layer 120, or may not horizontally surround the wavelength converting layer 120 at all. To partially horizontally surround the wavelength converting layer may mean that at least one imaginary line extending away from and perpendicular to a sidewall of the wavelength converting layer 120 (or the LED 115) intersects with an optical barrier 130 with at most a side coating 125 in between, while fully horizontally surround the element means that all such perpendicular lines extending away the element meets that criteria.

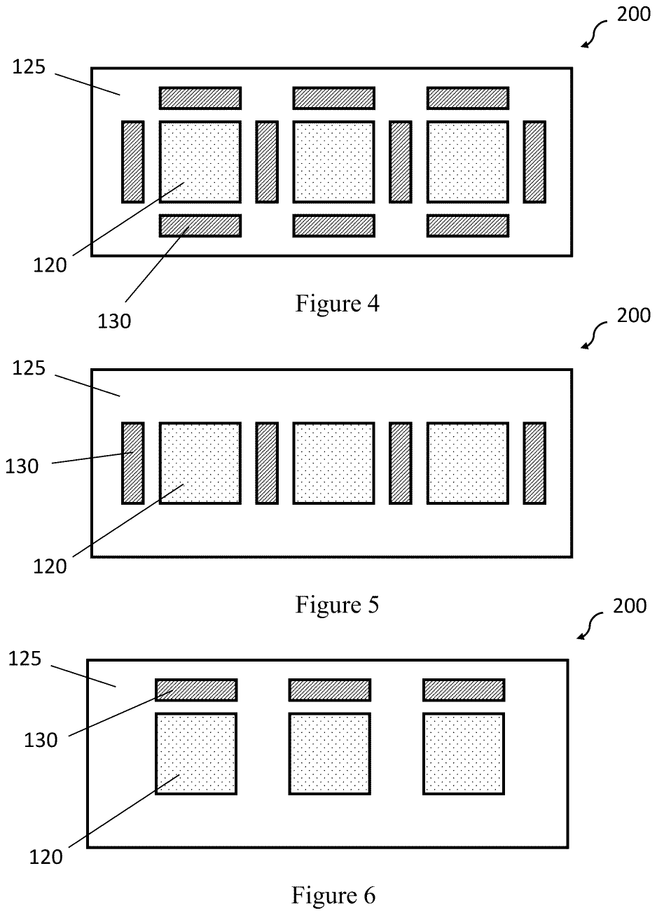

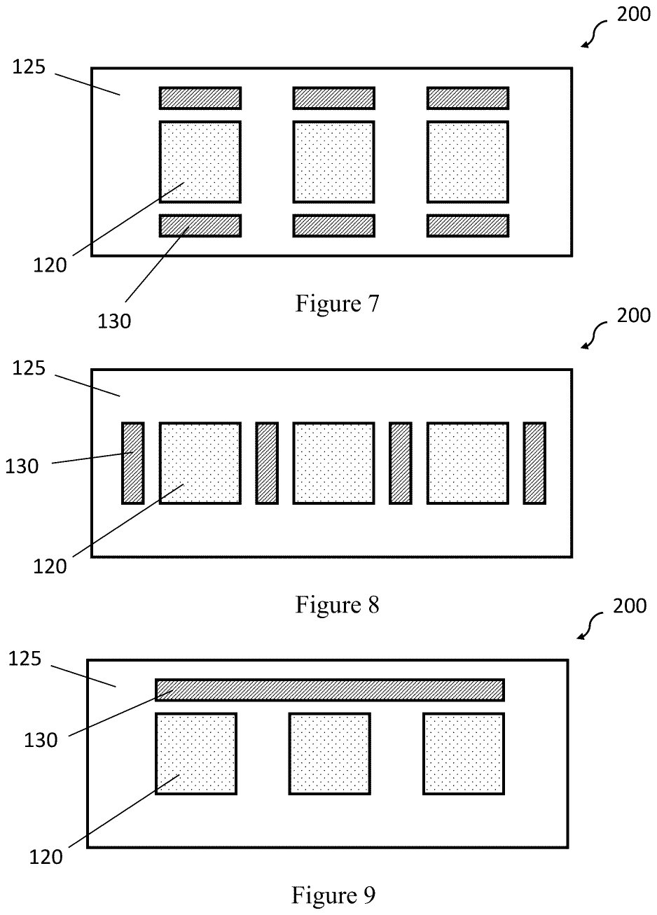

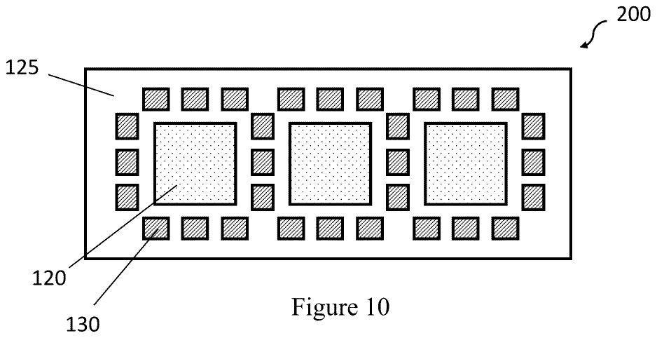

The optical barrier 130 can also be patterned in numerous ways in horizontal directions, forming shapes like dotted or dashed lines as opposed to a single long channel extending from one side of the array to the other, or a grid encircling one or multiple LEDs. Multiple light emitting devices 100 or components of the light emitting device 100 may be part of an array 200. In FIGS. 4-10, the array 200 is seen in plan view looking down a vertical direction perpendicular to the plane of the substrate 105. The wavelength converting layer 120 and/or the LED 115 under the wavelength converting layer 120 may be surrounded or partially surrounded by one or more optical barriers 130. For example, the optical barriers 130 each disposed at a side of the wavelength converting layer 120 may have a length equal to that side of the wavelength converting layer 120, and be disposed adjacent only to that side of the wavelength converting layer 120, as shown in FIGS. 4-8. Alternatively, the optical barrier 130 may have a length unequal to a side of the wavelength converting layer 120 along which it is disposed (e.g., the side or sides it is closest to), as shown in FIG. 9. In FIG. 9 the optical barrier 130 has a greater length than the side and/or collective sides of the wavelength converting layer 120 it is disposed in. The optical barrier 130 may alternatively have a lesser length than the side instead, such as shown in FIG. 10. That is, the optical barrier 130 may have a greater length, equal length, or lesser length than the side of the LED 115 it is adjacent to. When an LED 115 or wavelength converting layer 120 has an optical barrier 130 disposed adjacent to it, the side coating 125 may be the only element between the LED 115 or wavelength converting layer 120 and the optical barrier 130. Alternatively, the optical barrier 130 may be in direct contact with the LED 115 or wavelength converting layer 120 when it is considered adjacent.

In FIG. 9 the optical barrier 130 may extend fully or partially across more than one side of more than one wavelength converting layer 120 and/or LEDs 115. That is, multiple wavelength converting layers 120 and/or LEDs 115 may share one integral optical barrier 130 along one or more sides, which may also extend between the gaps between those elements. In FIG. 9, the shared optical barrier 130 does not fully horizontally surround any wavelength converting layer 120 and/or LED 115, being adjacent only to one side of the wavelength converting layers 120 and/or LEDs 115. Additionally or alternatively, multiple optical barriers 130 adjacent to different sides of a single wavelength converting layer 120 and/or LED 115 may be disconnected and spaced apart from each other, as shown in FIGS. 4-5, 7-8, and 10. Multiple optical barriers 130 in an array, and/or adjacent to a single wavelength converting layer 120 and/or LED 115, may be of a same shape (such as square or rectangular) and/or size. Alternatively, some or all optical barriers 130 in an array may have differing shapes and/or sizes. Some sides of a wavelength converting layer 120 and/or LED 115 may have no optical barriers 130 adjacent to them. For example, in FIGS. 6 and 9, three out of the four sides of the wavelength converting layer 120 and/or LED 115 may have no optical barriers 130 adjacent to them.

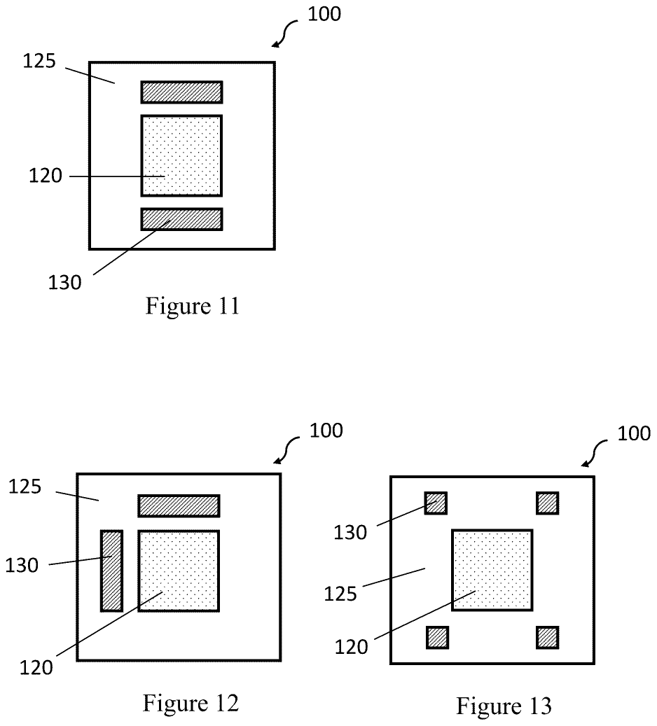

Further configurations in plan view are shown for single light emitting devices 100 in FIGS. 11-13. Notably, FIG. 13 shows optical barriers 130 which are disposed adjacent to the corners of the wavelength converting layer 120 without extending along the sides of the wavelength converting layer 120, where the optical barriers 130 have a square shape rather than a rectangular one.

In summary, the optical barrier 130 may be disposed to not entirely surround any one of the LEDs 115 and/or wavelength converting layers 120, that is, to have at least one gap in the optical barrier 130 adjacent to the LED 115 and/or wavelength converting layer 120 when viewed down the vertical direction. In other words, the optical barrier 130 may not form an unbroken shape, whether a polygon, circle, oval, or otherwise, around any LED 115 and/or wavelength converting layer 120. The optical barriers 130 may form partial shapes around individual LEDs 115 instead, as shown for example in FIGS. 11-13 where the optical barriers 130 form parts of a rectangle or square. The partial shape may be a same shape as that of the wavelength converting layer 120 or LED 115, although this is not a requirement.

A more detailed definition is given here for when an optical barrier 130 may be described to be disposed “at or adjacent to” a side of the wavelength converting layer 120 and/or LED 115. Firstly, a side of the wavelength converting layer 120 and/or the LED 115 may extend in a first horizontal direction. An optical barrier 130 is disposed at or adjacent to that side when, in a second horizontal direction traveling away from the LED 115 and perpendicular to the first horizontal direction, any portion of an optical barrier 130 is disposed (with only side coating 125 as an intervening element, or no intervening element at all). Similarly, no optical barrier 130 is disposed at or adjacent to that side when in that second horizontal direction, no portion of any optical barrier 130 is disposed (or at least no part of optical barrier 130 is disposed without an intervening element that is not the side coating 125, such as another wavelength converting layer 120 or LED 115). Under this definition, for example, FIG. 13 shows optical barriers 130 disposed around the wavelength converting layer 120 without being disposed at or adjacent to any of the sides of the wavelength converting layer 120 (‘around’ or ‘partially surround’ may mean an element is in direct contact with, or spaced apart from another element with only the side coating 125 in between, whether or not the element is adjacent to the other element). In the respective second horizontal directions perpendicular to the respective first horizontal directions of the wavelength converting layer 120 sides, there are no optical barriers 130 disposed. That is, the optical barriers 130 are placed around the wavelength converting layer 120 without extending to any sides of the wavelength converting layer 120 in a horizontal direction. In contrast, FIG. 4 shows each of the wavelength converting layers 120 with optical barriers 130 disposed on all four sides, though without completely encircling any one of the wavelength converting layers 120 since there are gaps at the corners.

Each of the optical barriers 130 shown in FIGS. 4-13 may have cross sections similar or the same as those shown respectively in FIGS. 1-3 (gaps above, below, or both) or may alternatively extend vertically through the entire side coating 125 without any gaps.

In embodiments of the invention, optical barriers 130 may be made by various steps, such as sawing a channel through side coat material between LEDs, filling with optical barrier material, etching/planarization step, side coat fill and side coat planarization. One or more of these steps may be omitted or rearranged.

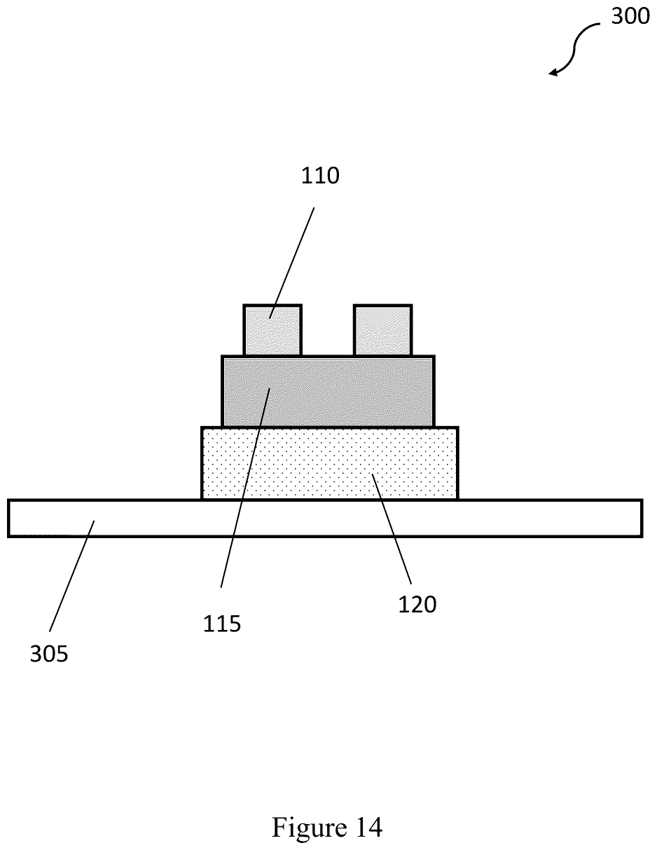

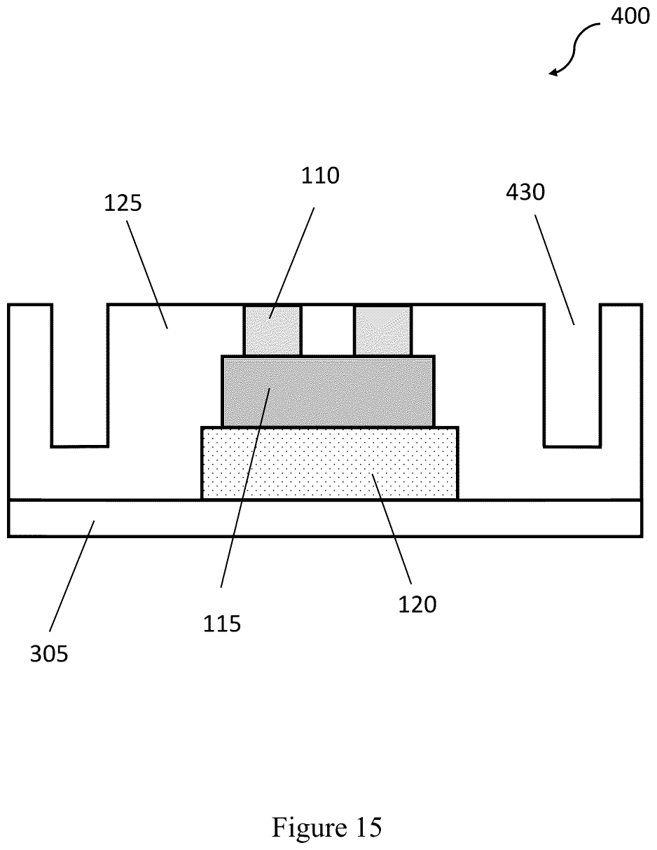

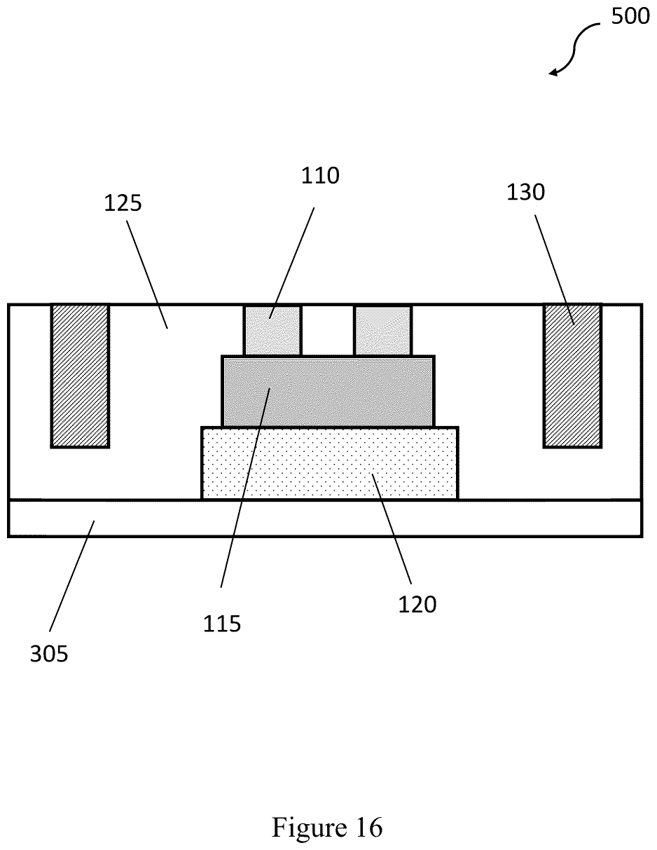

FIGS. 14-17 show a method of making the device according to embodiments of the invention. In a flip chip process starting at 300, the LED 115 and/or the wavelength converting layer 120 may be attached in a flipped configuration on a tape 305 before the side coating 125 is disposed upon them. At 400, the depth of the saw can be controlled such that the channel 430 does not extend down to the tape 305 that the LED 115 is mounted on before flipping and attaching to the substrate 105. This can be used to control the depth of the optical barrier 130 from the top of the side coating 125 by repeating the previously disclosed steps while the parts are flipped over on tape 305. Namely, at 500 the channels 430 may be filled with optical barrier material, etched and/or planarized. Then the structure may be removed from the tape, flipped, and attached to the substrate 105, resulting in the light emitting device 100 as shown in e.g., FIG. 2.

Alternatively or additionally, the side coating 125 disposition, sawing, filling, etching/planarization may be done on the substrate 105 with the LED 115 and wavelength converting layer 120 in non-flipped orientation rather than on a tape 305. For example, the sawing may be done from the top of the side coating 125 where the depth of sawing defines the gap between the optical barrier 130 and the substrate 105 instead.

Alternatively or additionally, the structure on the substrate 105 may include a channel 430 fully through side coating 125 filled with optical barrier material, such as a result of a flip-chip process. Then, the optical barrier material may be partially sawed through from the top, and etched back to define gap between the optical barrier 130 to top of the side coating 125. The gap can be filled from the top with side coat material leaving the optical barrier 130 embedded from top and bottom in side coating 125.

Laser etching capability exists to achieve line widths down to 5 um line width and 5 um position tolerance (DC or pulsed, UV laser). The optical barrier 130 material, e.g., epoxy or silicone, is expected to etch more readily than clear/white silicone used in the side coating 125. Using a laser etcher with 3D position control allows removal of the black barrier material from certain regions after it has filled the saw channel and been planarized. The laser can be tuned to remove black material in order to modulate its height (Z direction or vertical direction, from full thickness to fully removed) along horizontal (X-Y directions) in the channel. With this method (among others), the optical barrier 130 between light emitters can be modulated/patterned with additional degrees of freedom.

This disclosure is illustrative and not limiting. Further modifications will be apparent to one skilled in the art in light of this disclosure and are intended to fall within the scope of the appended claims.

What is claimed is:

1. A light source comprising:
a substrate with a substrate surface extending in a horizontal direction;
a light emitting structure disposed on the substrate surface of the substrate, the light emitting structure comprising a light emitting device and a light emitting surface facing away from the substrate;
at least one optical barrier spaced apart from to the light emitting structure and comprising a top surface facing away from the substrate, a bottom surface facing the substrate and opposite the top surface, and side walls extending between the top surface and the bottom surface in a vertical direction perpendicular to the horizontal direction, wherein the at least one optical barrier is at least one of:
spaced apart from the substrate in the vertical direction;
disposed without being flush with the light emitting surface of the light emitting structure in the vertical direction; and
disposed without entirely horizontally surrounding the light emitting structure.

2. The light source of claim 1, wherein the light emitting structure comprises a wavelength converting layer, the wavelength converting layer comprising the light emitting surface of the light emitting structure.

3. The light source of claim 2, wherein the at least one optical barrier is vertically spaced apart from the light emitting surface.

4. The light source of claim 3, wherein the at least one optical barrier vertically spaced apart from the substrate.

5. The light source of claim 1, further comprising a side coating disposed around the light emitting structure comprising a top surface flush with the light emitting surface.

6. The light source of claim 1, further comprising a side coating disposed between the light emitting structure and the at least one optical barrier.

7. The light source of claim 6, wherein the side coating comprises silicone.

8. The light source of claim 1, wherein the at least one optical barrier comprises silicone.

9. The light source of claim 1, wherein the at least one optical barrier comprises a first optical barrier and a second optical barrier disposed on the substrate spaced apart from the first optical barrier.

10. The light source of claim 9, wherein the light emitting structure comprises second side walls, the first optical barrier disposed adjacent to an entirety of the first side wall.

11. The light source of claim 10, wherein the first side wall of the second side walls extends in a first horizontal direction, a second side wall of the second side walls extending in a second horizontal direction perpendicular to the first horizontal direction, and the second optical barrier is disposed adjacent to an entirety of the second side wall.

12. The light source of claim 10, wherein the first side wall of the second side walls extends in a first horizontal direction, a second side wall of the side walls is disposed opposite the first side wall and extending in the first horizontal direction, the second optical barrier is disposed adjacent to an entirety of the second side wall.

13. The light source of claim 9, wherein the at least one optical barrier has a lesser length in the horizontal direction than length of the light emitting structure in the horizontal direction.

14. The light source of claim 1, further comprising a second light emitting device disposed on the substrate and spaced apart from the light emitting structure, wherein the light emitting structure comprises second side walls, the second light emitting device comprises third side walls, and one of the at least one optical barrier is adjacent to one of the first side walls and to one of the second side walls.

15. The light source of claim 1, further comprising a second light emitting device disposed on the substrate and spaced apart from the light emitting structure, wherein the light emitting structure comprises second side walls, the second light emitting device comprises third side walls, a first optical barrier of the at least one optical barrier is adjacent to the second side walls, and a second optical barrier of the at least one optical barrier is adjacent to one of the third side walls and spaced apart from the first optical barrier.

16. The light source of claim 1, wherein the at least one optical barrier is spaced apart from the substrate in the vertical direction.

17. The light source of claim 1, wherein the at least one optical barrier is disposed without being flush with the light emitting surface of the light emitting structure in the vertical direction.

18. The light source of claim 1, wherein the at least one optical barrier is disposed without entirely horizontally surrounding the light emitting structure.

19. A method for producing a light source, comprising:
disposing side coating material around a light emitting device;
sawing through the side coating material to form a trench in the side coating material that does not extend completely through the side coating material;
forming the optical barrier in the trench; and
disposing the light emitting device, side coating material, and optical barrier on a substrate.

20. The method of claim 19, wherein disposing the optical barrier on the substrate places the optical barrier in direct contact with the substrate.
